(19) United States
(12) Patent Application Publication
(10) Pub. No.: US 2020/0408808 A1
(43) Pub. Date: Dec. 31, 2020

(54) INFORMATION PROVIDING APPARATUS, INFORMATION PROVIDING METHOD, AND SYSTEM

(71) Applicant: HONDA MOTOR CO., LTD., Tokyo (JP)

(72) Inventors: Yoshihiro MATSUNAGA, Wako-shi (JP); Sho TAKADA, Wako-shi (JP); Mitsuhiro ITO, Wako-shi (JP); Nobuyuki SASAKI, Wako-shi (JP); Ryo OSHIMA, Wako-shi (JP); Mio OSHIMA, Wako-shi (JP)

(21) Appl. No.: 17/018,798

(22) Filed: Sep. 11, 2020

Related U.S. Application Data
(63) Continuation of application No. PCT/JP2018/044478, filed on Dec. 4, 2018.

(30) Foreign Application Priority Data
Mar. 20, 2018 (JP) 2018-053085

(51) Int. Cl. G01R 11/56; H02J 7/00; G06Q 30/06; G06Q 30/02

(52) U.S. Cl. CPC G01R 11/56; G06Q 30/0283; G06Q 30/0645; H02J 7/0047

(57) ABSTRACT

The present invention provides an information providing apparatus including a providing unit configured to determine whether electric power stored in a storage battery, included in a portable electric power supply device, that stores electric power to be supplied to electrical equipment detachably connected, can be sold or whether to store electric power in the storage battery, and provide a result of the determination to a user of the electric power supply device, wherein in a case where the providing unit determines that stored electric power can be sold, purchase processing is performed on the stored electric power in accordance with a kind of the electrical equipment inferred, and in a case where the providing unit determines that electric power is to be stored in the storage battery, electric power storing processing is performed on the storage battery in accordance with the kind of the electrical equipment inferred.

### CROSS-REFERENCE TO RELATED APPLICATION(S)

This application is a continuation of International Patent Application No. PCT/JP2018/044478 filed on Dec. 4, 2018, which claims priority to and the benefit of Japanese Patent Application No. 2018-53085 filed on Mar. 20, 2018, the entire disclosures of which are incorporated herein by reference.

### TECHNICAL FIELD

The present invention relates to an information providing apparatus, an information providing method, and a system.

### BACKGROUND ART

Techniques of collecting and managing information on equipment over a communication network have been proposed (see PTL 1 and PTL 2). PTL 1 discloses a system in which an electricity company purchases surplus electric power generated by an electric power generator of an electric power generation company and supplies such electric power directly to an electric power user from the electric power generation company through a power grid. PTL 2 discloses a server to which a battery rental service company sets rental fees for batteries based on amounts of electricity that can be stored in the batteries and that charges a rental fee for a battery provided to a user.

### CITATION LIST

### Patent Literature

### PTL 1: Japanese Patent Laid-Open No. 2002-271982

### PTL 2: Japanese Patent Laid-Open No. 2011-118638

### SUMMARY OF INVENTION

### Technical Problem

Portable electric power supply devices, typically portable electric power generators and portable batteries have recently come into widespread use for recreation and business activities, as an electric power source for electrical equipment used outside. Thus, there is a desire for a technique that manages (utilizes) surplus electric power of a portable electric power supply device usefully for a user of the electric power supply device and a provider of the electric power supply device (e.g., a rental service company of the electric power supply device, etc.).

Therefore, an objective of the present invention is to provide a technique having an advantage in managing surplus electric power of a portable electric power supply device.

### Solution to Problem

The present invention provides an information providing apparatus including a receiving unit configured to receive, from a portable electric power supply device including a storage battery that stores electric power to be supplied to electrical equipment detachably connected, electric power information relating to an amount of electric power stored in the storage battery and a feature quantity relating to electric power supplied to the electrical equipment, a storage unit configured to retain the electric power information and the feature quantity received by the receiving unit with user identification information used for identifying a user of the electric power supply device associated with the electric power information, a providing unit configured to determine, based on the electric power information retained in the storage unit, whether electric power stored in the storage battery can be sold or whether to store electric power in the storage battery, and provide a result of the determination to the user of the electric power supply device, and an inferring unit configured to infer a kind of the electrical equipment based on the feature quantity retained in the storage unit, wherein in a case where the providing unit determines that electric power stored in the storage battery can be sold, purchase processing is performed on the electric power stored in the storage battery in accordance with the kind of the electrical equipment inferred by the inferring unit, and in a case where the providing unit determines that electric power is to be stored in the storage battery, electric power storing processing is performed on the storage battery in accordance with the kind of the electrical equipment inferred by the inferring unit.

The present invention provides an information providing method including a server receiving, from a portable electric power supply device including a storage battery that accumulates electric power to be supplied to electrical equipment detachably connected, electric power information relating to an amount of electric power stored in the storage battery and a feature quantity relating to electric power supplied to the electrical equipment, the server retaining the electric power information and the feature quantity received with user identification information used for identifying a user of the electric power supply device associated with the electric power information, the server determining, based on the electric power information retained, whether electric power stored in the storage battery can be sold or whether to store electric power in the storage battery, and providing a result of the determination to the user of the electric power supply device, and inferring a kind of the electrical equipment based on the feature quantity retained, wherein in a case where it is determined that electric power stored in the storage battery can be sold, purchase processing is performed on the electric power stored in the storage battery in accordance with the kind of the electrical equipment inferred, and in a case where it is determined that electric power is to be stored in the storage battery, electric power storing processing is performed on the storage battery in accordance with the kind of the electrical equipment inferred.

The present invention provides a system being a system including a portable electric power supply device including a storage battery that stores electric power to be supplied to electrical equipment detachably connected, and an information providing apparatus that can communicate with the electric power supply device over a network, wherein the information providing apparatus includes a receiving unit configured to receive, from the electric power supply device, electric power information relating to an amount of electric power stored in the storage battery and a feature quantity relating to electric power supplied to the electrical equipment, a storage unit configured to retain the electric power information and the feature quantity received by the receiving unit with user identification information used for identifying a user of the electric power supply device associated with the electric power information, a providing unit configured to determine, based on the electric power information retained in the storage unit, whether electric power stored in the storage battery can be sold or whether to store electric power in the storage battery, and provide a result of the determination to the user of the electric power supply device, and an inferring unit configured to infer a kind of the electrical equipment based on the feature quantity retained in the storage unit, wherein in a case where the providing unit determines that electric power stored in the storage battery can be sold, purchase processing is performed on the electric power stored in the storage battery in accordance with the kind of the electrical equipment inferred by the inferring unit, and in a case where the providing unit determines that electric power is to be stored in the storage battery, electric power storing processing is performed on the storage battery in accordance with the kind of the electrical equipment inferred by the inferring unit.

### Advantageous Effects of Invention

According to the present invention, a technique having an advantage in managing surplus electric power of a portable electric power supply device can be provided.

Other features and advantages of the present invention will be apparent from the following description taken in conjunction with the accompanying drawings.

### BRIEF DESCRIPTION OF DRAWINGS

The accompanying drawings, which are incorporated in and constitute a part of the specification, illustrate embodiments of the invention and, together with the description, serve to explain principles of the invention.

FIG. 1 is a schematic diagram illustrating a configuration of an information providing system as an aspect of the present invention.

FIG. 2 is a schematic block diagram illustrating a configuration of the electric power supply device illustrated in FIG. 1.

FIG. 3 is a schematic block diagram illustrating a configuration of an information providing apparatus illustrated in FIG. 1.

FIG. 4 is a schematic block diagram illustrating a configuration of a terminal illustrated in FIG. 1.

FIG. 5 is a flowchart used for describing an example of processing by the information providing system illustrated in FIG. 1.

FIG. 6 is a schematic block diagram illustrating another configuration of the electric power supply device illustrated in FIG. 1.

### DESCRIPTION OF EMBODIMENTS

A preferred embodiment of the present invention will be described below with reference to the attached drawings. Note that, in each drawing, the same reference numerals are given to the same members, and redundant description thereof is omitted.

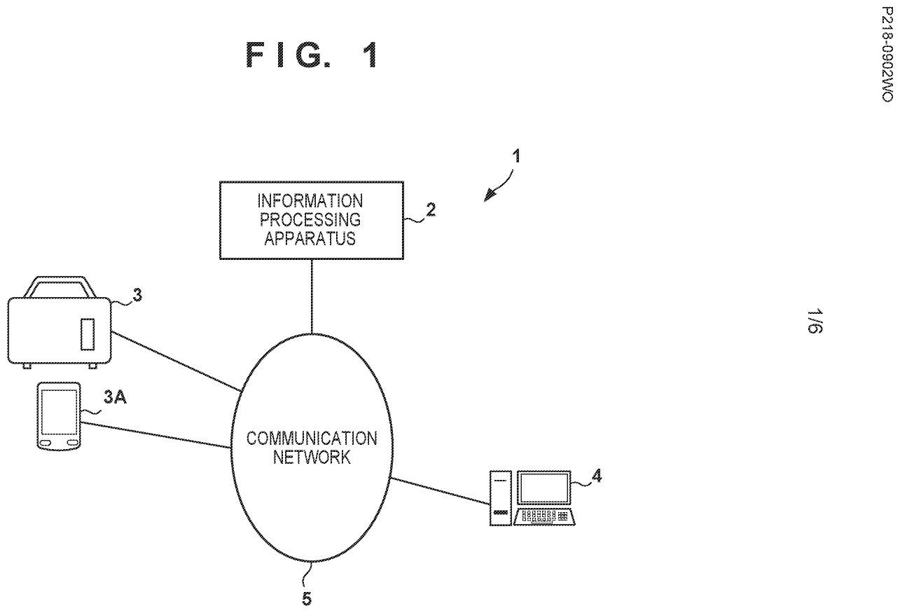

FIG. 1 is a schematic diagram illustrating a configuration of an information providing system 1 as an aspect of the present invention. The information providing system 1 includes an information providing apparatus 2, a portable electric power supply device 3 (hereinafter, simply referred to as “electric power supply device 3”), a user terminal 3A, and a terminal 4. In the information providing system 1, the information providing apparatus 2, the electric power supply device 3, the user terminal 3A, and the terminal 4 are connected to each other over a communication network 5, being able to communicate with each other. Although FIG. 1 illustrates, as an example, a case where one electric power supply device 3 (user terminal 3A) and one terminal 4 constitute the information providing system 1 by way of example, numbers of electric power supply devices 3 (user terminals 3A) and terminals 4 constituting the information providing system 1 may be each more than one.

The information providing apparatus 2 is formed of, for example, a computer including a CPU, memory, and the like and functions as an information providing server in the information providing system 1.

The electric power supply device 3 is a device that supplies electric power to electrical equipment and is a portable device rather than a stationary device. The electric power supply device 3 is therefore carried to a site of use in accordance with its user's application such as for recreation, for business, and in emergency. The electric power supply device 3 may be either owned by the user or rented from a rental service company.

The user terminal 3A is a terminal used by the user of the electric power supply device 3 and, for example, a computer or a portable terminal including a CPU, memory, and the like. The user terminal 3A includes a display device and a communication device. In the present embodiment, information to be provided to the user of the electric power supply device 3 is provided (transmitted) from the information providing apparatus 2 to the user terminal 3A. However, in a case where the electric power supply device 3 has functions equivalent to those of the user terminal 3A, it is possible to provide the electric power supply device 3 with the information to be provided to the user of the electric power supply device 3. In addition, the user of the electric power supply device 3 may be allowed to select (set) one of the user terminal 3A and the electric power supply device 3 as a destination of the information provided from the information providing apparatus 2.

The terminal 4 is a terminal used by a service provider that manages the information providing apparatus 2 (information providing system 1) and is, for example, a computer or a portable terminal including a CPU, memory, and the like. The terminal 4 includes a display device and a communication device. Here, the service provider is a company that provides the user of the electric power supply device 3 with information useful for such a user; examples of the service provider include a service distributor of the electric power supply device 3, a rental service company of the electric power supply device 3, an electricity company, and a dealer in vehicles (motorcycles, four-wheel vehicles, etc.).

In the information providing system 1, the information providing apparatus 2 collects (receives), from the electric power supply device 3 over the communication network 5 such as the Internet, electric power information relating to an amount of electric power stored (accumulated) in the electric power supply device 3. In addition, the information providing apparatus 2 determines, based on the collected electric power information, whether the electric power stored in the electric power supply device 3 can be sold or whether to store (charge) electric power in the electric power supply device 3, and provides a result of such determination to the user of the electric power supply device 3.

With the information provided from the information providing apparatus 2, the user of the electric power supply device 3 can determine whether to sell the electric power stored in the electric power supply device 3, or whether to store electric power in the electric power supply device 3, and thus can obtain information useful in using the electric power supply device 3. The service provider that manages the information providing apparatus 2 can obtain the electric power information relating to the electric power stored in the electric power supply device 3, and thus, for example, the service provider can obtain information useful in enticing users to an electric power trading facility operated by the service provider itself.

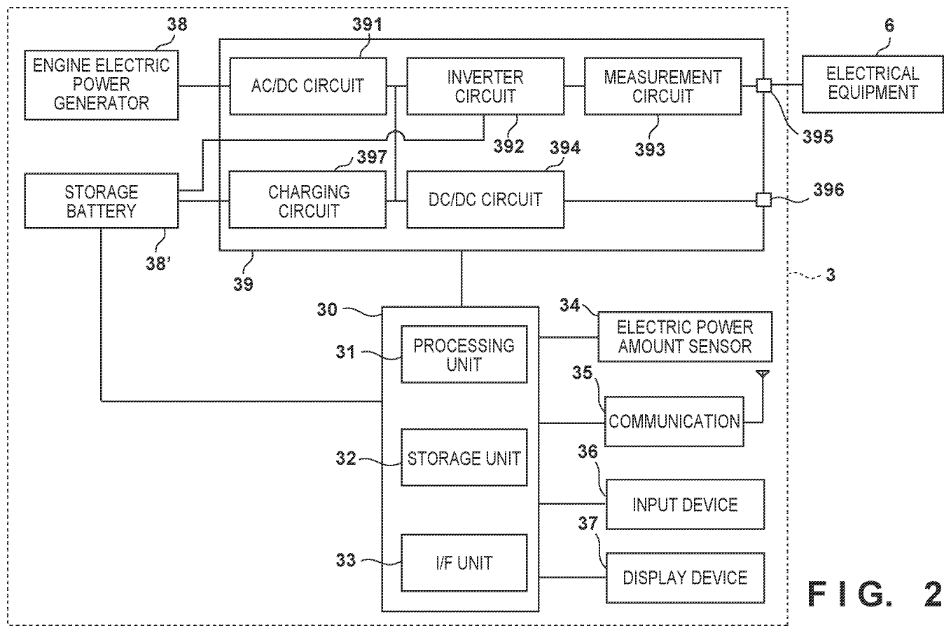

FIG. 2 is a schematic block diagram illustrating a configuration of the electric power supply device 3. The electric power supply device 3 is, in the present embodiment, a generator-type electric power supply device that includes an engine electric power generator 38, a storage battery 38′, an electric power circuit 39, a control circuit 30, an electric power amount sensor 34, a communication device 35, an input device 36, and a display device 37.

The engine electric power generator 38 is driven by fuel to generate AC power. Examples of the fuel include gasoline, liquefied petroleum gas, and hydrogen.

The storage battery 38′ includes, for example, a secondary battery such as lithium-ion battery and stores electric power generated by the engine electric power generator 38. The storage battery 38′ outputs, for example, DC voltage at 48 V. The storage battery 38′ can store electric power generated by an external electric power generator or the like or electric power provided from an external battery.

The electric power circuit 39 is a circuit that converts voltage generated by the engine electric power generator 38 into predetermined AC or DC. The electric power circuit 39 includes an AC/DC circuit 391, an inverter circuit 392, a measurement circuit 393, a DC/DC circuit 394, and a charging circuit 397.

The AC/DC circuit 391 includes a rectifying-smoothing circuit that rectifies and smooths the AC generated by the engine electric power generator 38. The inverter circuit 392 includes a circuit that converts DC output from the AC/DC circuit 391 or the DC supplied from the storage battery 38′ into a stable AC of a predetermined frequency.

The measurement circuit 393 includes a current sensor and a voltage sensor, measures AC voltage and AC current supplied from the inverter circuit 392 to electrical equipment 6 connected to an AC outlet 395, and outputs a result of the measurement to the control circuit 30. To the AC outlet 395, the electrical equipment 6 that can be driven by AC power is detachably connected. The electrical equipment 6 includes various kinds of electrical apparatuses; examples of the electrical equipment 6 include cooking appliances (hot plate, kettle, microwave oven, grill, mixer, etc.), air conditioners, televisions, luminaires, dryers, power tools, large light fixtures, and compressors.

The DC/DC circuit 394 converts a level of the DC voltage output from the AC/DC circuit 391, and DC voltage at the converted level is supplied to the control circuit 30 or the like as operating voltage or output through a DC outlet 396. To the DC outlet 396, the electrical equipment 6 that can be driven by DC power is detachably connected.

The charging circuit 397 charges the storage battery 38′ with the electric power generated by the engine electric power generator 38. Even after, for example, fuel for the engine electric power generator 38 runs out, the electric power supply device 3 can supply the electric power stored in the storage battery 38′ to the electrical equipment 6.

The control circuit 30 is a circuit for controlling the electric power supply device 3. The control circuit 30 includes a processing unit 31, a storage unit 32, and an interface (I/F) unit 33. The processing unit 31 includes a processor, typically a CPU, and executes a program retained in the storage unit 32. The storage unit 32 includes a storage device such as a RAM, a ROM, and a hard disk. In the storage unit 32, the program to be executed by the processing unit 31 and various kinds of data are retained (stored). The I/F unit 33 relays signals transmitted and received between an external device and the processing unit 31.

The electric power amount sensor 34 detects an amount of electric power stored in the storage battery 38′. To the electric power amount sensor 34, any technique known in the industry is applicable, such as a voltage method in which the amount of electric power stored in the storage battery 38′ is determined by measuring a terminal voltage of the storage battery 38′, a coulomb counting method in which the amount of electric power stored in the storage battery 38′ is determined by measuring current flowing into the storage battery 38′ and current flowing out from the storage battery 38′, a battery cell modeling method in which the coulomb counting method is employed in combination with a database that stores discharge properties and temperature properties of the storage battery 38′, and an impedance tracking method in which the amount of electric power stored in the storage battery 38′ is determined by capturing an impedance of the storage battery 38′.

The communication device 35 is a wireless communication device or a wired communication device that performs information communication with the information providing apparatus 2 over the communication network 5. The input device 36 is a device that receives operation input by the user of the electric power supply device 3, and includes, for example, a plurality of switches. The display device 37 is a device that displays information to the user of the electric power supply device 3, and includes, for example, an image display device such as a liquid crystal display (LCD) and a light-emitting element such as a light-emitting diode (LED).

The processing unit 31 transmits a result of the detection by the electric power amount sensor 34 to the information providing apparatus 2 via the communication device 35, as electric power information relating to the amount of electric power accumulated in the storage battery 38′. The processing unit 31 also transmits the result of the measurement by the measurement circuit 393 to the information providing apparatus 2 via the communication device 35. The result of the measurement by the measurement circuit 393 is available as information relating to a kind of the electrical equipment 6 connected to the AC outlet 395 of the electric power supply device 3; for example, the result is available for inferring the kind of the electrical equipment 6. The electric power supplied from the electric power supply device 3 to the electrical equipment 6 shows a waveform (feature quantities) that characterizes the kind of the electrical equipment 6. Therefore, such feature quantities enable the inference of the kind of the electrical equipment 6 connected to the AC outlet 395.

Examples of the feature quantities include apparent power and power factor. The power factor may be calculated by dividing active power by apparent power or may be calculated as a cosine of a phase difference θ (cos θ) between voltage and current. In a case where the power factor is calculated as a cosine of a phase difference between voltage and current, the measurement circuit 393 measured the phase difference θ. Moreover, the feature quantities may include a time taken by the electrical equipment 6 for its stable operation since its startup or may include a peak value of starting current which flows through the electrical equipment 6 at a time of the startup of the electrical equipment 6. Relations between the feature quantities and kinds of the electrical equipment 6 are then converted into data beforehand as a feature quantity map, and such a feature quantity map is compared with (checked against) feature quantities obtained from the result of the measurement by the measurement circuit 393, by which the kind of the electrical equipment 6 can be inferred.

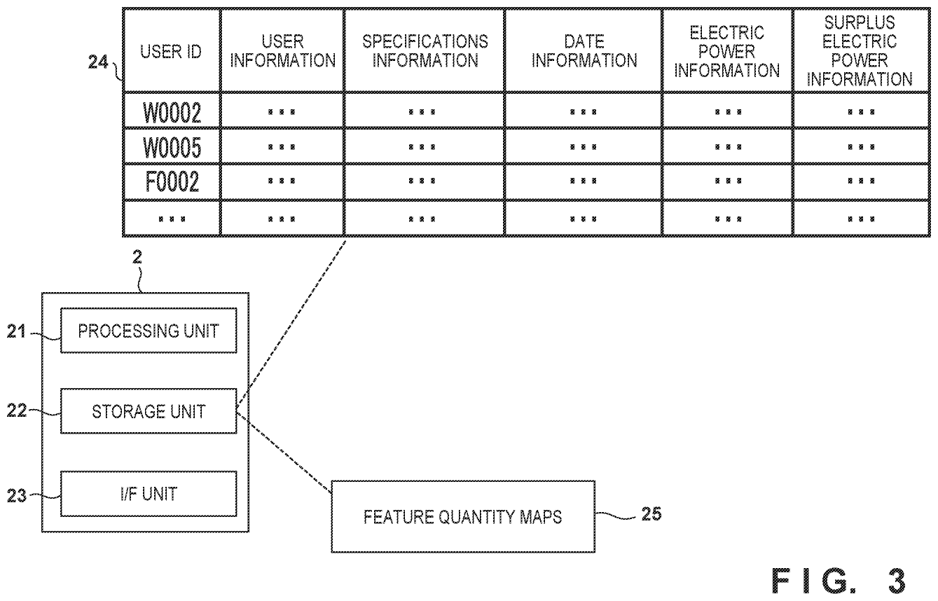

FIG. 3 is a schematic block diagram illustrating a configuration of the information providing apparatus 2. The information providing apparatus 2 includes a processing unit 21, a storage unit 22, and an interface (I/F) unit 23. The processing unit 21 includes a processor, typically a CPU, and executes a program retained in the storage unit 22. The storage unit 22 includes a storage device such as a RAM, a ROM, and a hard disk. The I/F unit 23 relays signals transmitted and received between an external device and the processing unit 21. The I/F unit 23 includes a wired or wireless communication interface that can communicate with the electric power supply device 3, the user terminal 3A, and the terminal 4 over the communication network 5.

In the storage unit 22, the program to be executed by the processing unit 21 and various kinds of data are retained (stored). In the present embodiment, as illustrated in FIG. 3, databases 24 and 25 are exemplified as the data retained in the storage unit 22.

The database 24 is a database that accumulates pieces of information relating to electric power supply devices 3 and users of the electric power supply devices 3. “User ID” is an identifier that is preassigned for recognizing (identifying) a user of an electric power supply device 3, namely, user identification information. “User Information” is information relating to the user of the electric power supply device 3 recognized with the “User ID” and includes, for example, a name, an address, and an email address. “Specifications Information” is information relating to specifications of an electric power supply device 3 and includes, for example, specifications of a storage battery 38′, more specifically, an amount of electric power that can be stored in the storage battery 38′ (power storage capacity). “Date Information” is information relating to a date of receiving electric power information relating to an amount of electric power stored in the storage battery 38′ transmitted from the electric power supply device 3 and includes, for example, a year, month, and day. “Electric Power Information” retains (stores) the electric power information received from the electric power supply device 3, namely, the amount of electric power accumulated in the storage battery 38′ of the electric power supply device 3. “Surplus Electric Power Information” retains a surplus amount of electric power of the electric power supply device 3 that is calculated by the processing unit 21 based on the power storage capacity of the storage battery 38′ obtained from “Specifications Information” and the amount of electric power stored in the storage battery 38′ obtained from “Electric Power Information”. The processing unit 21 sets, for example, 10% of the power storage capacity of the storage battery 38′ as a minimum amount of electric power necessary for the storage battery 38′, and determines an amount of electric power obtained by subtracting the minimum amount of electric power from the amount of electric power stored in the storage battery 38′ as the surplus amount of electric power. Note that the amount of electric power stored in the storage battery 38′ obtained from “Electric Power Information” itself may be determined as the surplus amount of electric power.

The database 25 is a database that accumulates feature quantity maps. The processing unit 21 compares the feature quantity maps with the result of the measurement by the measurement circuit 393 transmitted from the electric power supply device 3 to infer the kind of the electrical equipment 6 connected to the AC outlet 395 of the electric power supply device 3. In the present embodiment, although the kind of the electrical equipment 6 connected to the AC outlet 395 is inferred by the information providing apparatus 2, the kind of the electrical equipment 6 connected to the AC outlet 395 may be inferred by the electric power supply device 3, and a result of the inference may be transmitted (provided) to the information providing apparatus 2.

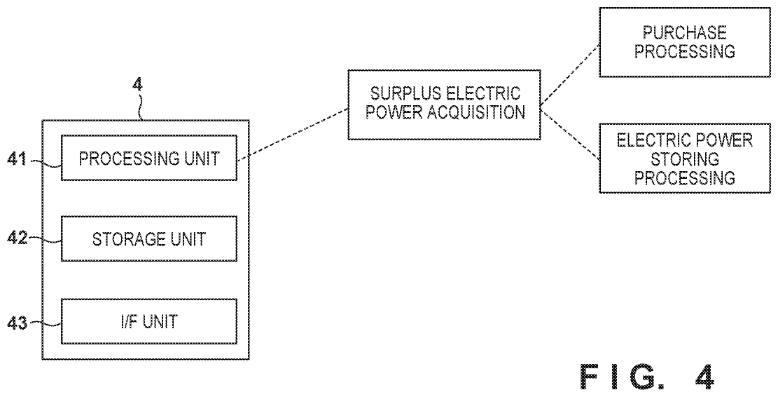

FIG. 4 is a schematic block diagram illustrating a configuration of the terminal 4. The terminal 4 is installed in, for example, an electric power trading facility operated by the service provider that manages the information providing apparatus 2. The terminal 4 includes a processing unit 41, a storage unit 42, and an interface (I/F) unit 43. The processing unit 41 includes a processor, typically a CPU, and executes a program retained in the storage unit 42. The storage unit 42 includes a storage device such as a RAM, a ROM, and a hard disk. The I/F unit 43 relays signals transmitted and received between an external device and the processing unit 41. The I/F unit 43 includes a wired or wireless communication interface that can communicate with the information providing apparatus 2, the user terminal 3A, and the terminal 4 over the communication network 5.

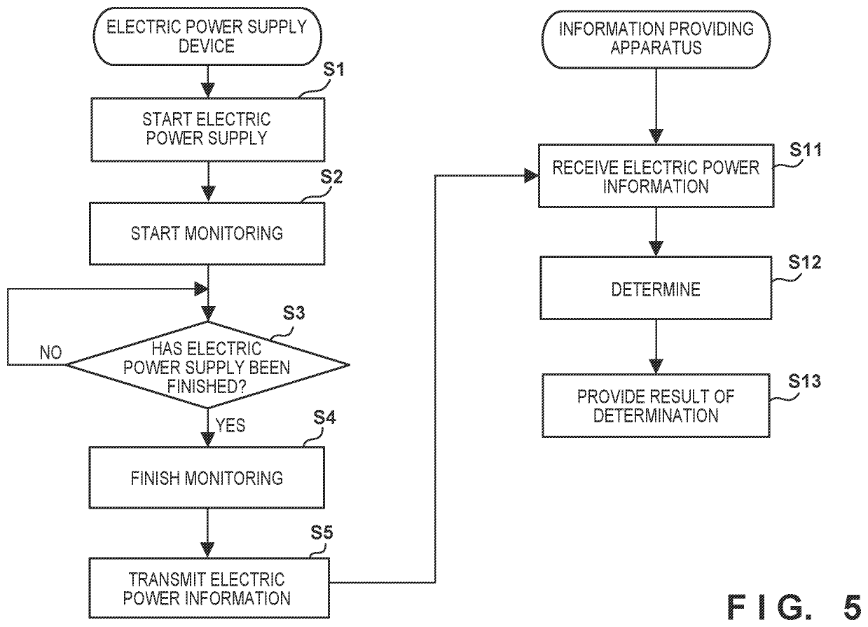

Referring to FIG. 5, an example of processing by the information providing system 1 will be described. Here, an example of processing performed between the information providing apparatus 2 and the electric power supply device 3 will be mainly described. The processing illustrated in FIG. 5 is performed by the processing unit 21 in the information providing apparatus 2 and performed by the processing unit 31 in the electric power supply device 3.

In S1, supply of electric power to the electrical equipment 6 is started in the electric power supply device 3. In the present embodiment, electric power stored in the storage battery 38′ of the electric power supply device 3 is supplied to the electrical equipment 6. At this point, concurrently with the start of the supply of the electric power from the storage battery 38′ to the electrical equipment 6, generation of electric power by the engine electric power generator 38 may be started, and the electric power generated by the engine electric power generator 38 may be stored in the storage battery 38′.

In S2, monitoring of the electric power amount sensor 34 and the measurement circuit 393 is started. Upon the start of the monitoring, results of the detection by the electric power amount sensor 34 and results of the measurement by the measurement circuit 393 are accumulated in the storage unit 32 every predetermined sampling period.

In S3, whether the supply of the electric power from the electric power supply device 3 to the electrical equipment 6 has been finished is determined. Such determination can be performed using, for example, the results of the detection by the electric power amount sensor 34 and the results of the measurement by the measurement circuit 393. In a case where the supply of the electric power from the electric power supply device 3 to the electrical equipment 6 has been finished, the processing proceeds to S4 to finish the monitoring of the electric power amount sensor 34 and the measurement circuit 393. In a case where the supply of the electric power from the electric power supply device 3 to the electrical equipment 6 has not been finished, S3 is repeated every predetermined period.

In S5, the results of the detection by the electric power amount sensor 34 accumulated in the storage unit 32 are transmitted to the information providing apparatus 2 as electric power information relating to an amount of electric power accumulated in the storage battery 38′. The electric power information is transmitted to the information providing apparatus 2 together with a user ID used for identifying a user of the electric power supply device 3 and specifications information relating to the specifications of the electric power supply device 3 associated with the electric power information. In the present embodiment, the electric power information is information indicating a history of the amount of electric power stored in the storage battery 38′, but only electric power information at a time when the supply of the electric power from the electric power supply device 3 to the electrical equipment 6 is finished may be transmitted to the information providing apparatus 2. In the present embodiment, the electric power information is transmitted after the supply of the electric power from the electric power supply device 3 to the electrical equipment 6 has been finished, but note that this does not limit the present invention; the electric power information may be transmitted in real time. Together with the electric power information, the results of the measurement by the measurement circuit 393 accumulated in the storage unit 32 may be transmitted to the information providing apparatus 2.

In S11, in the information providing apparatus 2, the electric power information associated with the user ID and the specifications information that is transmitted from the electric power supply device 3 is received. Then, based on the electric power information received from the electric power supply device 3, the database 24 is updated. Specifically, the amount of electric power stored in the storage battery 38′ of the electric power supply device 3, which is included in the received electric power information, is retained in “Electric Power Information” of the database 24 with the user ID associated with the amount of electric power. Additionally, as described above, a surplus amount of electric power is calculated based on the electric power information and the specifications information received from the electric power supply device 3 and retained in “Surplus Electric Power Information” of the database 24. Furthermore, a date (year, month, and day) when the electric power information is received is retained in “Date Information” of the database 24.

In S12, based on the electric power information received in S11, whether the electric power stored in the storage battery 38′ of the electric power supply device 3 can be sold or whether to store electric power in the storage battery 38′ is determined. For example, “Surplus Electric Power Information” of the database 24 is referred to, and in a case where the surplus amount of electric power is not less than a preset reference amount of electric power, it is determined that the electric power stored in the storage battery 38′ of the electric power supply device 3 can be sold, or in a case where the surplus amount of electric power is less than the reference amount of electric power, it is determined that electric power is to be stored in the storage battery 38′. Regarding the reference amount of electric power serving as a reference for the determination, any amount of electric power can be set in accordance with the user of the electric power supply device 3 or the specifications of the electric power supply device 3, and for example, the reference amount of electric power is preset by the service provider that manages the information providing apparatus 2. Rather than setting the reference amount of electric power, it may be determined that the electric power stored in the storage battery 38′ of the electric power supply device 3 can be sold in a case where the surplus amount of electric power is not zero, or it may be determined that electric power is to be stored in the storage battery 38′ in a case where the surplus amount of electric power is zero.

In S13, a result of the determination in S12 is provided (notified) to the user of the electric power supply device 3. In the present embodiment, the result of the determination in S12 is transmitted from the information providing apparatus 2 to the user terminal 3A.

For example, in a case where it is determined in S12 that the electric power stored in the storage battery 38′ of the electric power supply device 3 can be sold, an image (image data) showing a location where the electric power stored in the storage battery 38′ can be sold, for example, an electric power trading facility operated by the service provider, is transmitted to the user terminal 3A to cause the user terminal 3A to display such an image. At this time, in a case where the information providing apparatus 2 receives current position information relating to a current position of the electric power supply device 3, an image showing an electric power trading facility nearest to the current position of the electric power supply device 3 out of electric power trading facilities at which the electric power stored in the storage battery 38′ of the electric power supply device 3 can be sold is preferably transmitted to the user terminal 3A, based on such current position information.

In contrast, in a case where it is determined in S12 that the electric power is to be stored in the storage battery 38′ of the electric power supply device 3, an image (image data) showing a location where the storing of the electric power in the storage battery 38′ can be performed, for example, an electric power trading facility operated by the service provider, is transmitted to the user terminal 3A to cause the user terminal 3A to display such an image. At this time, in a case where the information providing apparatus 2 receives current position information relating to a current position of the electric power supply device 3, an image showing an electric power trading facility nearest to the current position of the electric power supply device 3 out of electric power trading facilities at which the storing of the electric power in the storage battery 38′ of the electric power supply device 3 can be performed is preferably transmitted to the user terminal 3A, based on such current position information.

As seen from the above, in the present embodiment, the result of the determination (S12) as to whether the electric power stored in the storage battery 38′ of the electric power supply device 3 can be sold or whether to store electric power in the storage battery 38′ is provided from the information providing apparatus 2 to the user of the electric power supply device 3. This enables the user of the electric power supply device 3 to decide to sell the electric power stored in the storage battery 38′ or to store electric power to the storage battery 38′, in accordance with, for example, a usage plan of the electric power supply device 3. Since the user of the electric power supply device 3 is provided with the location where the electric power stored in the storage battery 38′ can be sold or the location where the storing of the electric power in the storage battery 38′ can be performed, that is, the electric power trading facility, the user is enabled to save time and trouble to look for the electric power trading facility by himself or herself. At the same time, the service provider that manages the information providing apparatus 2 can grasp an electric power storage state of the storage battery 38′ of the electric power supply device 3 and provide the user of the electric power supply device 3, in accordance with the electric power storage state, with information that the electric power stored in the storage battery 38′ can be sold or that electric power is to be stored in the storage battery 38′, and additionally, for example, can provide information regarding an electric power trading facility operated by the service provider to entice the user of the electric power supply device 3 to the electric power trading facility operated by the service provider itself

In the present embodiment, a timing for determining whether the electric power stored in the storage battery 38′ of the electric power supply device 3 can be sold or whether to store electric power in the storage battery 38′ and automatically providing the result of the determination to the user of the electric power supply device 3 is when the supply of electric power from the electric power supply device 3 to the electrical equipment 6 is finished, but this does not limit the present invention. For example, whether the electric power stored in the storage battery 38′ of the electric power supply device 3 can be sold or whether to store electric power in the storage battery 38′ may be determined while electric power is being supplied from the electric power supply device 3 to the electrical equipment 6, and a result of the determination may be automatically provided to the user of the electric power supply device 3. In addition, whether the electric power stored in the storage battery 38′ of the electric power supply device 3 can be sold or whether to store electric power in the storage battery 38′ may be determined in response to a request from the user of the electric power supply device 3 (i.e., with any timing), and a result of the determination may be provided to the user of the electric power supply device 3.

Here, a case where the user of the electric power supply device 3 brings the electric power supply device 3 to an electric power trading facility to sell the electric power stored in the storage battery 38′ of the electric power supply device 3 or to store electric power in the storage battery 38′ will be described. In such an electric power trading facility, a terminal 4 used by the service provider that manages the information providing apparatus 2 is installed, as described above.

The processing unit 41 of the terminal 4 acquires, via the I/F unit 43, “Surplus Electric Power Information” relating to the electric power supply device 3 brought to the electric power trading facility, namely, a surplus amount of electric power of such an electric power supply device 3, from the storage unit 22 (database 24) of the information providing apparatus 2. At this time, the processing unit 41 acquires, from the information providing apparatus 2, in addition to “Surplus Electric Power Information”, the result of the determination (S12) as to whether the electric power stored in the storage battery 38′ of the electric power supply device 3 can be sold or whether to store electric power in the storage battery 38′. However, the terminal 4 (processing unit 41) may determine, based on “Surplus Electric Power Information” acquired from the information providing apparatus 2, whether the electric power stored in the storage battery 38′ of the electric power supply device 3 can be sold or whether to store electric power in the storage battery 38′. In this case, the reference amount of electric power serving as the reference for the determination is preferably shared with the information providing apparatus 2 so as not to produce variations in such determination.

In the case where the electric power stored in the storage battery 38′ of the electric power supply device 3 can be sold, the processing unit 41 of the terminal 4 performs purchase processing for purchasing an amount of electric power specified by the user of the electric power supply device 3 out of the surplus amount of electric power of the electric power supply device 3. The purchase processing includes a process of calculating an added value equivalent to the amount of electric power to be purchased (e.g., a purchase price or a point to be given to the user), a process of notifying the user of the calculated added value, a process of providing the user with the calculated added value with consent of the user to sell the electric power, and a process of transmitting a result of the purchase processing to the information providing apparatus 2. In the process of calculating the added value equivalent to the amount of electric power to be purchased, an added value more than usual may be calculated in a case where, for example, the electrical equipment 6 inferred from the result of the measurement by the measurement circuit 393 is electrical equipment specified by the service provider. The result of the purchase processing transmitted from the terminal 4 to the information providing apparatus 2 is, for example, accumulated in “User Information” of the database 24 of the information providing apparatus 2.

In contrast, in the case where electric power is to be stored in the storage battery 38′ of the electric power supply device 3, the processing unit 41 of the terminal 4 performs electric power storing processing for storing electric power in the storage battery 38′ in an amount of electric power specified by the user. The electric power storing processing includes a process of calculating a price equivalent to the amount of electric power to be stored, a process of notifying the user of the calculated price, a process of transmitting a result of the electric power storing processing to the information providing apparatus 2, and the like. In the process of calculating the price equivalent to the amount of electric power to be stored, a price discount from a usual price may be calculated in a case where, for example, the electrical equipment 6 inferred from the result of the measurement by the measurement circuit 393 is electrical equipment specified by the service provider. The result of the electric power storing processing transmitted from the terminal 4 to the information providing apparatus 2 is, for example, accumulated in “User Information” of the database 24 of the information providing apparatus 2.

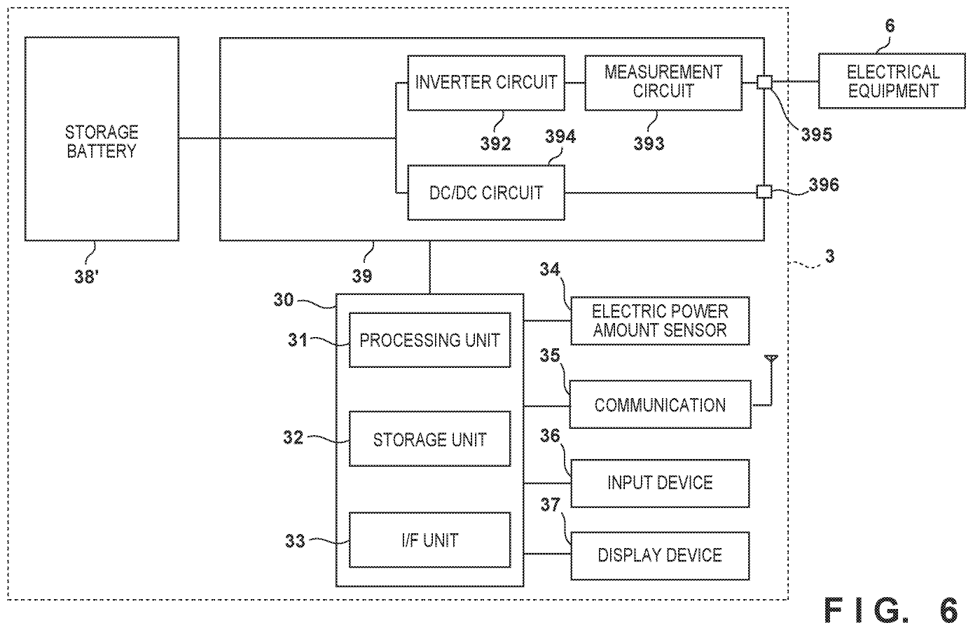

The electric power supply device 3 illustrated in FIG. 2 includes the engine electric power generator 38, but this does not limit the electric power supply device 3. For example, as illustrated in FIG. 6, the electric power supply device 3 may not include the engine electric power generator 38. This case dispenses with the AC/DC circuit 391 and the charging circuit 397. FIG. 6 is a schematic block diagram illustrating another configuration of the electric power supply device 3.

### Summary of Embodiment

1. The information providing apparatus in the above-described embodiment (e.g., 2) is including:

a receiving unit (e.g., 23) configured to receive, from a portable electric power supply device (e.g., 3) including a storage battery (e.g., 38′) that stores electric power to be supplied to electrical equipment (e.g., 6) detachably connected, electric power information relating to an amount of electric power stored in the storage battery;

a storage unit (e.g., 22) configured to retain the electric power information received by the receiving unit with user identification information used for identifying a user of the electric power supply device associated with the electric power information; and

a providing unit (e.g., 21) configured to determine, based on the electric power information retained in the storage unit, whether electric power stored in the storage battery can be sold or whether to store electric power in the storage battery, and provide a result of the determination to the user of the electric power supply device.

According to this embodiment, a technique that enables the user to determine (recognize) information useful in using the electric power supply device, for example, whether to sell the electric power stored in the electric power supply device, or whether to store electric power in the electric power supply device can be provided.

2. The above-described information providing apparatus (e.g., 2),

wherein the providing unit (e.g., 21) calculates a surplus amount of electric power of the electric power supply device from a specification of the storage battery and the electric power information retained in the storage unit, and performs the determination based on the surplus amount of electric power.

According to this embodiment, whether the electric power stored in the electric power supply device can be sold, or whether to store electric power in the storage battery can be determined from an actual surplus amount of electric power of the electric power supply device.

3. The above-described information providing apparatus (e.g., 2),

wherein the providing unit (e.g., 21)

determines that the electric power stored in the storage battery can be sold in a case where the surplus amount of electric power is not less than a preset reference amount of electric power, and

determines that electric power is to be stored in the storage battery in a case where the surplus amount of electric power is less than the reference amount of electric power.

According to this embodiment, whether the electric power stored in the electric power supply device can be sold, or whether to store electric power in the storage battery can be determined based on the preset (presettable) reference amount of electric power.

4. The above-described information providing apparatus (e.g., 2),

wherein the providing unit (e.g., 21)

determines that electric power is to be stored in the storage battery in a case where the surplus amount of electric power is zero, and

determines that the electric power stored in the storage battery can be sold in a case where the surplus amount of electric power is not zero.

According to this embodiment, whether the electric power stored in the electric power supply device can be sold, or whether to store electric power in the storage battery can be determined in accordance with whether the surplus amount of electric power is zero.

5. The above-described information providing apparatus (e.g., 2),

wherein in a case where the providing unit (e.g., 21) determines that the electric power stored in the storage battery can be sold, the providing unit notifies the user of the electric power supply device of a location where the electric power stored in the storage battery can be sold.

According to this embodiment, a user of an electric power supply device who wants to sell electric power can be enticed to a location intended by a service provider that manages an information providing apparatus (e.g., electric power trading facility).

6. The above-described information providing apparatus (e.g., 2), wherein

the receiving unit (e.g., 23) receives current position information relating to a current position of the electric power supply device, and

based on the current position information received by the receiving unit, the providing unit (e.g., 21) notifies the user of the electric power supply device of a location nearest to the current position of the electric power supply device out of locations where the electric power stored in the storage battery can be sold.

According to this embodiment, a user of an electric power supply device who wants to sell electric power can be enticed to a location nearest to a current position of the electric power supply device out of locations intended by a service provider that manages an information providing apparatus (e.g., electric power trading facilities).

7. The above-described information providing apparatus (e.g., 2),

wherein in a case where the providing unit determines that electric power is to be stored in the storage battery, the providing unit notifies the user of the electric power supply device of a location where electric power can be stored in the storage battery.

According to this embodiment, a user of an electric power supply device who wants to store electric power can be enticed to a location intended by a service provider that manages an information providing apparatus (e.g., electric power trading facility).

8. The above-described information providing apparatus (e.g., 2), wherein

the receiving unit receives current position information relating to a current position of the electric power supply device, and

based on the current position information received by the receiving unit, the providing unit notifies the user of the electric power supply device of a location nearest to the current position of the electric power supply device out of locations where electric power can be stored in the storage battery.

According to this embodiment, a user of an electric power supply device who wants to store electric power can be enticed to a location nearest to a current position of the electric power supply device out of locations intended by a service provider that manages an information providing apparatus (e.g., electric power trading facilities).

9. An information providing method in the above-described embodiment including:

a server (e.g., 2) receiving, from a portable electric power supply device (e.g., 3) including a storage battery (e.g., 38′) that accumulates electric power to be supplied to electrical equipment (e.g., 6) detachably connected, electric power information relating to an amount of electric power stored in the storage battery;

the server retaining the electric power information received with user identification information used for identifying a user of the electric power supply device associated with the electric power information; and

the server determining, based on the electric power information retained, whether electric power stored in the storage battery can be sold or whether to store electric power in the storage battery, and providing a result of the determination to the user of the electric power supply device.

According to this embodiment, a technique that enables the user to determine (recognize) information useful in using the electric power supply device, for example, whether to sell the electric power stored in the electric power supply device, or whether to store electric power in the electric power supply device can be provided.

10. A system in the above-described embodiment (e.g., 1) is

a system including a portable electric power supply device (e.g., 3) including a storage battery (e.g., 38′) that stores electric power to be supplied to electrical equipment (e.g., 6) detachably connected, and an information providing apparatus (e.g., 2) that can communicate with the electric power supply device over a network,

wherein the information providing apparatus includes:

a receiving unit (e.g., 23) configured to receive, from the electric power supply device, electric power information relating to an amount of electric power stored in the storage battery;

a storage unit (e.g., 22) configured to retain the electric power information received by the receiving unit with user identification information used for identifying a user of the electric power supply device associated with the electric power information; and

a providing unit (e.g., 21) configured to determine, based on the electric power information retained in the storage unit, whether electric power stored in the storage battery can be sold or whether to store electric power in the storage battery, and provide a result of the determination to the user of the electric power supply device.

According to this embodiment, a technique that enables the user to determine (recognize) information useful in using the electric power supply device, for example, whether to sell the electric power stored in the electric power supply device, or whether to store electric power in the electric power supply device can be provided.

11. The above-described system (e.g., 1),

wherein the electric power supply device (e.g., 2)

includes an electric power generator (e.g., 38) configured to generate electric power, and

stores the electric power generated by the electric power generator in the storage battery.

According to this embodiment, in addition to the storage battery, the electric power supply device can include an electric power generator used for storing electric power in the storage battery.

Preferred embodiments according to the present invention are described above, but it should be appreciated that the present invention is not limited to these embodiments, and various modifications and changes are possible within the spirit of the present invention.

1. An information providing apparatus comprising:
a receiving unit configured to receive, from a portable electric power supply device including a storage battery that stores electric power to be supplied to electrical equipment detachably connected, electric power information relating to an amount of electric power stored in the storage battery and a feature quantity relating to electric power supplied to the electrical equipment;
a storage unit configured to retain the electric power information and the feature quantity received by the receiving unit with user identification information used for identifying a user of the electric power supply device associated with the electric power information;
a providing unit configured to determine, based on the electric power information retained in the storage unit, whether electric power stored in the storage battery can be sold or whether to store electric power in the storage battery, and provide a result of the determination to the user of the electric power supply device; and
an inferring unit configured to infer a kind of the electrical equipment based on the feature quantity retained in the storage unit,
wherein in a case where the providing unit determines that electric power stored in the storage battery can be sold, purchase processing is performed on the electric power stored in the storage battery in accordance with the kind of the electrical equipment inferred by the inferring unit, and in a case where the providing unit determines that electric power is to be stored in the storage battery, electric power storing processing is performed on the storage battery in accordance with the kind of the electrical equipment inferred by the inferring unit.

2. The information providing apparatus according to claim 1, wherein the providing unit calculates a surplus amount of electric power of the electric power supply device from a specification of the storage battery and the electric power information retained in the storage unit, and performs the determination based on the surplus amount of electric power.

3. The information providing apparatus according to claim 2, wherein
the providing unit
determines that the electric power stored in the storage battery can be sold in a case where the surplus amount of electric power is not less than a preset reference amount of electric power, and
determines that electric power is to be stored in the storage battery in a case where the surplus amount of electric power is less than the reference amount of electric power.

4. The information providing apparatus according to claim 2, wherein
the providing unit
determines that electric power is to be stored in the storage battery in a case where the surplus amount of electric power is zero, and
determines that the electric power stored in the storage battery can be sold in a case where the surplus amount of electric power is not zero.

5. The information providing apparatus according to claim 1, wherein in a case where the providing unit determines that the electric power stored in the storage battery can be sold, the providing unit notifies the user of the electric power supply device of a location where the electric power stored in the storage battery can be sold.

6. The information providing apparatus according to claim 5, wherein
the receiving unit receives current position information relating to a current position of the electric power supply device, and
based on the current position information received by the receiving unit, the providing unit notifies the user of the electric power supply device of a location nearest to the current position of the electric power supply device out of locations where the electric power stored in the storage battery can be sold.

7. The information providing apparatus according to claim 1, wherein in a case where the providing unit determines that electric power is to be stored in the storage battery, the providing unit notifies the user of the electric power supply device of a location where electric power can be stored in the storage battery.

8. The information providing apparatus according to claim 7, wherein
the receiving unit receives current position information relating to a current position of the electric power supply device, and
based on the current position information received by the receiving unit, the providing unit notifies the user of the electric power supply device of a location nearest to the current position of the electric power supply device out of locations where electric power can be stored in the storage battery.

9. An information providing method comprising:
a server receiving, from a portable electric power supply device including a storage battery that accumulates electric power to be supplied to electrical equipment detachably connected, electric power information relating to an amount of electric power stored in the storage battery and a feature quantity relating to electric power supplied to the electrical equipment;
the server retaining the electric power information and the feature quantity received with user identification information used for identifying a user of the electric power supply device associated with the electric power information;
the server determining, based on the electric power information retained, whether electric power stored in the storage battery can be sold or whether to store electric power in the storage battery, and providing a result of the determination to the user of the electric power supply device; and
inferring a kind of the electrical equipment based on the feature quantity retained,
wherein in a case where it is determined that electric power stored in the storage battery can be sold, purchase processing is performed on the electric power stored in the storage battery in accordance with the kind of the electrical equipment inferred, and in a case where it is determined that electric power is to be stored in the storage battery, electric power storing processing is performed on the storage battery in accordance with the kind of the electrical equipment inferred.

10. A system being a system including a portable electric power supply device including a storage battery that stores electric power to be supplied to electrical equipment detachably connected, and an information providing apparatus that can communicate with the electric power supply device over a network,
wherein the information providing apparatus includes:
a receiving unit configured to receive, from the electric power supply device, electric power information relating to an amount of electric power stored in the storage battery and a feature quantity relating to electric power supplied to the electrical equipment;
a storage unit configured to retain the electric power information and the feature quantity received by the receiving unit with user identification information used for identifying a user of the electric power supply device associated with the electric power information;
a providing unit configured to determine, based on the electric power information retained in the storage unit, whether electric power stored in the storage battery can be sold or whether to store electric power in the storage battery, and provide a result of the determination to the user of the electric power supply device; and
an inferring unit configured to infer a kind of the electrical equipment based on the feature quantity retained in the storage unit,
wherein in a case where the providing unit determines that electric power stored in the storage battery can be sold, purchase processing is performed on the electric power stored in the storage battery in accordance with the kind of the electrical equipment inferred by the inferring unit, and in a case where the providing unit determines that electric power is to be stored in the storage battery, electric power storing processing is performed on the storage battery in accordance with the kind of the electrical equipment inferred by the inferring unit.

11. The system according to claim 10,
wherein the electric power supply device
includes an electric power generator configured to generate electric power, and
stores the electric power generated by the electric power generator in the storage battery.
